(19) United States
(12) Patent Application Publication
(10) Pub. No.: US 2019/0341272 A1
(43) Pub. Date: Nov. 7, 2019

(54) SUBSTRATE PROCESSING APPARATUS, SUBSTRATE PROCESSING SYSTEM, AND SUBSTRATE PROCESSING METHOD

(71) Applicant: Tokyo Electron Limited, Tokyo (JP)

(72) Inventors: Yoshinori Ikeda, Kumamoto (JP); Shota Umezaki, Kumamoto (JP); Kenji Nishi, Kumamoto (JP)

(21) Appl. No.: 16/395,488

(22) Filed: Apr. 26, 2019

(30) Foreign Application Priority Data
May 1, 2018 (JP) 2018-088253

(51) Int. Cl. H01L 21/67; H01L 21/677; H01L 21/673

(52) U.S. Cl. CPC H01L 21/6715; H01L 21/67393; H01L 21/67781; H01L 21/6773

(57) ABSTRACT

A substrate processing apparatus according to the present disclosure includes: a substrate processing unit; a partition wall; and a liquid supply source. The substrate processing unit includes a substrate holder and performs a liquid processing on a substrate. The partition wall serves as a partition wall between a first space from a carry-in/out port through which the substrate is carried in/out to the substrate processing unit, and a second space other than the first space. The liquid supply source is provided in the second space and supplies a processing liquid to the substrate.

### CROSS-REFERENCE TO RELATED APPLICATIONS

This application is based on and claims priority from Japanese Patent Application No. 2018-088253, filed on May 1, 2018, with the Japan Patent Office, the disclosure of which is incorporated herein in its entirety by reference.

### TECHNICAL FIELD

The present disclosure relates to a substrate processing apparatus, a substrate processing system, and a substrate processing method.

### BACKGROUND

In a substrate processing apparatus of related art which processes a substrate such as, for example, a semiconductor wafer (hereinafter, referred to as a “wafer”), an air atmosphere cleaned by using a fan filter unit (FFU) is supplied into a housing (see, e.g., Japanese Patent Application Laid-Open No. 2001-319845).

### SUMMARY

According to an aspect of the present disclosure, a substrate processing apparatus includes a substrate processing unit, a partition wall, and a liquid supply source. The substrate processing unit includes a substrate holder and performs a liquid processing on a substrate. The partition wall serves as a partition wall between a first space from a carry in/out port through which the substrate is carried in/out to the substrate processing unit, and a second space other than the first space. The liquid supply source is provided in the second space and supplies a processing liquid to the substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic view illustrating an outline of a configuration of a substrate processing system according to an exemplary embodiment.

FIG. 2 is a top view illustrating a configuration of a processing unit according to the exemplary embodiment.

FIG. 3 is a cross-sectional view taken along line A-A in FIG. 2.

FIG. 4A is a schematic view (1) illustrating a process of a liquid processing according to the exemplary embodiment.

FIG. 4B is a schematic view (2) illustrating a process of the liquid processing according to the exemplary embodiment.

FIG. 4C is a schematic view (3) illustrating a process of the liquid processing according to the exemplary embodiment.

FIG. 4D is a schematic view (4) illustrating a process of the liquid processing according to the exemplary embodiment.

FIG. 5A is a schematic view for explaining an example of an inflow suppression unit according to the exemplary embodiment.

FIG. 5B is a schematic view for explaining another example of the inflow suppression unit according to the exemplary embodiment.

FIG. 5C is a schematic view for explaining still another example of the inflow suppression unit according to the exemplary embodiment.

FIG. 6 is a top view illustrating a configuration of a processing unit according to Modification 1 of the exemplary embodiment.

FIG. 7 is a top view illustrating a configuration of a processing unit according to Modification 2 of the exemplary embodiment.

FIG. 8A is a schematic view (1) illustrating a process of a liquid processing by a processing unit according to Modification 3 of the exemplary embodiment.

FIG. 8B is a schematic view (2) illustrating a process of the liquid processing by the processing unit according to Modification 3 of the exemplary embodiment.

FIG. 8C is a schematic view (3) illustrating a process of the liquid processing by the processing unit according to Modification 3 of the exemplary embodiment.

FIG. 8D is a schematic view (2) illustrating a process of the liquid processing by the processing unit according to Modification 3 of the exemplary embodiment.

FIG. 9A is a schematic view (1) illustrating a process of a liquid processing by a processing unit according to Modification 4 of the exemplary embodiment.

FIG. 9B is a schematic view (2) illustrating a process of the liquid processing by the processing unit according to Modification 4 of the exemplary embodiment.

FIG. 9C is a schematic view (3) illustrating a process of the liquid processing by the processing unit according to Modification 4 of the exemplary embodiment.

FIG. 10 is a flowchart illustrating a procedure of the entire liquid processing according to the exemplary embodiment.

FIG. 11 is a flowchart illustrating a detailed procedure of the liquid processing according to the exemplary embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

Hereinafter, exemplary embodiments of a substrate processing apparatus, a substrate processing system, and a substrate processing method according to the present disclosure will be described in detail with reference to the accompanying drawings. The present disclosure is not limited by the exemplary embodiments described hereinbelow. It needs to be noted that the drawings are schematic, and the dimensional relationships, ratios, and etc. of respective elements may be different from the actual dimensional relationships and ratios. Further, portions included in the drawings may be different from each other in dimensional relationship and ratio.

In the substrate processing apparatus of the related art which processes a substrate such as, for example, a wafer, an air atmosphere cleaned by using the FFU is supplied into a housing.

Meanwhile, according to a processing, instead of the supply of the air atmosphere, the atmosphere around the wafer may be adjusted to a predetermined condition such as, for example, a low humidity or a low oxygen concentration. However, when the entire atmosphere inside the housing is adjusted to the predetermined condition with a gas for adjusting the atmosphere (hereinafter, referred to as an “atmosphere adjustment gas”), the use amount of the atmosphere adjustment gas may increase.

Thus, there is a demand for reducing the use amount of the atmosphere adjustment gas during the processing of the wafer.

<Outline of Substrate Processing System>

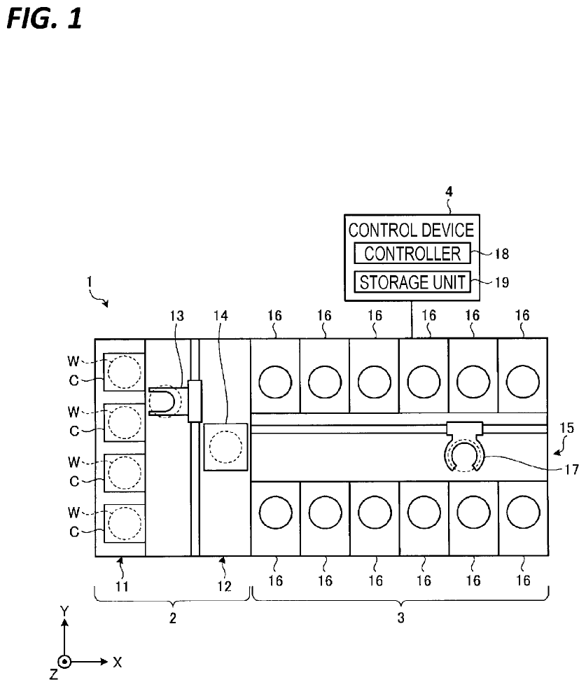

First, a schematic configuration of a substrate processing system 1 according to an exemplary embodiment will be described with reference to FIG. 1. FIG. 1 is a schematic view illustrating the schematic configuration of the substrate processing system 1 according to an exemplary embodiment. In the descriptions hereinafter, in order to clarify the positional relationships, an X axis, a Y axis, and a Z axis which are orthogonal to one another will be defined, and the positive direction of the Z axis will be defined as the vertically upward direction.

As illustrated in FIG. 1, the substrate processing system 1 includes a carry-in/out station 2 and a processing station 3. The carry-in/out station 2 and the processing station 3 are provided adjacent to each other.

The carry-in/out station 2 includes a carrier placing section 11 and a transfer section 12. In the carrier placing section 11, a plurality of carriers C are placed to accommodate a plurality of substrates, i.e., semiconductor wafers (hereinafter, “wafers W”) in the exemplary embodiment, in a horizontal state. Each wafer W is an example of the substrate.

The transfer section 12 is provided adjacent to the carrier placing section 11, and includes a substrate transfer device 13 and a delivery unit 14 therein. The substrate transfer device 13 is provided with a wafer holding mechanism configured to hold the wafer W. Further, the substrate transfer device 13 is movable horizontally and vertically and pivotable around a vertical axis. The substrate transfer device 13 transfers the wafer W between the carriers C and the delivery unit 14 by using the wafer holding mechanism.

The processing station 3 is provided adjacent to the transfer section 12. The processing station 3 includes a transfer section 15 and a plurality of processing units 16. The plurality of processing units 16 are arranged side by side at both sides of the transfer section 15. The transfer section 15 is an example of a common transfer path, and each processing unit 16 is an example of the substrate processing apparatus.

The transfer section 15 includes a substrate transfer device 17 therein. The substrate transfer device 17 is an example of a transfer mechanism, and is provided with a wafer holding mechanism configured to hold the wafer W. Further, the substrate transfer device 17 is movable horizontally and vertically and pivotable around a vertical axis. The substrate transfer device 17 transfers the wafer W between the delivery unit 14 and the processing units 16 by using the wafer holding mechanism.

Each processing unit 16 performs a predetermined liquid processing on the wafer W transferred by the substrate transfer device 17. Details of the processing unit 16 will be described later.

The substrate processing system 1 further includes a control device 4. The control device 4 is, for example, a computer and includes a controller 18 and a storage unit 19. The storage unit 19 stores programs for controlling various processings to be performed in the substrate processing system 1. The controller 18 controls the operation of the substrate processing system 1 by reading and executing the programs stored in the storage unit 19.

The programs may be recorded in a computer-readable recording medium, and installed from the recording medium to the storage unit 19 of the control device 4. The computer-readable recording medium may be, for example, a hard disk (HD), a flexible disk (FD), a compact disk (CD), a magnet optical disk (MO), or a memory card.

In the substrate processing system 1 configured as described above, first, the substrate transfer device 13 of the carry-in/out station 2 takes out the wafer W from a carrier C placed in the carrier placing section 11, and then, places the taken-out wafer W on the transfer unit 14. The wafer W placed on the transfer unit 14 is taken out from the transfer unit 14 by the substrate transfer device 17 of the processing station 3, and carried into the processing unit 16.

The wafer W carried into the processing unit 16 is processed by the processing unit 16, and then, carried out from the processing unit 16 by the substrate transfer device 17 to be placed on the delivery unit 14. The processed wafer W that has been placed on the delivery unit 14 returns to the carrier C of the carrier placing section 11 by the substrate transfer device 13.

<Outline of Processing Unit>

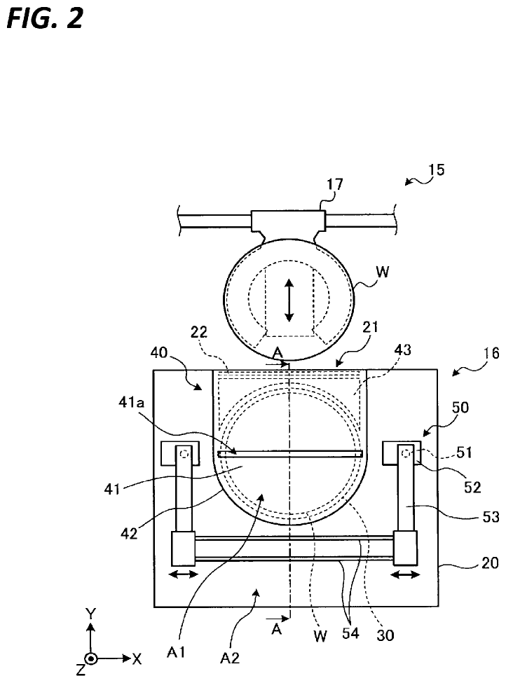

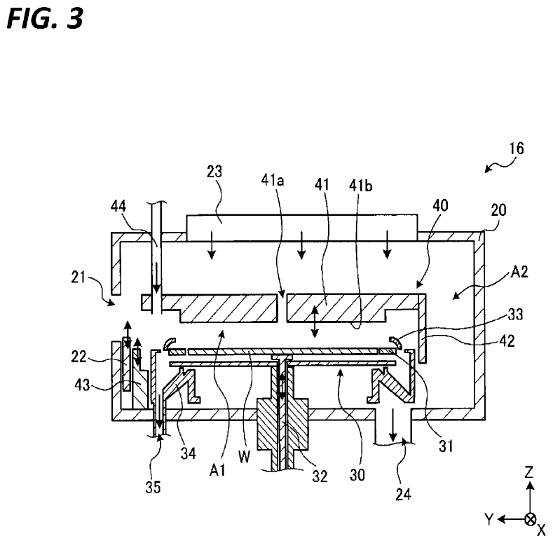

Next, an outline of the processing unit 16 will be described with reference to FIGS. 2 and 3. FIG. 2 is a top view illustrating a configuration of the processing unit 16 according to the exemplary embodiment, and FIG. 3 is a cross-sectional view taken along line A-A in FIG. 2. In addition, to facilitate the understanding, FIG. 3 represents the state of the carried-in wafer W, and omits an illustration of a linear motion (LM) guide 54.

As illustrated in FIG. 2, the processing unit 16 includes a housing 20, a substrate processing unit 30, a partition wall 40, and a liquid supply unit 50. The housing 20 accommodates the substrate processing unit 30, the partition wall 40, and the liquid supply unit 50.

The housing 20 has a carry-in/out port 21 at the position that faces the transfer section 15. The wafer W transferred by the substrate transfer device 17 of the transfer section 15 is carried into the housing 20 from the carry-in/out port 21. The housing 20 further has a shutter 22 configured to be able to open and close the carry-in/out port 21.

Further, as illustrated in FIG. 3, an FFU 23 is provided on the ceiling portion of the housing 20. The FFU 23 forms a downflow of the cleaned air atmosphere supplied into the housing 20. Further, an exhaust port 24 is formed on the bottom portion of the housing 20 to exhaust the air atmosphere supplied from the FFU 23 to the outside of the processing unit 16.

The substrate processing unit 30 performs a predetermined liquid processing on the wafer W. As illustrated in FIG. 3, the substrate processing unit 30 includes a substrate holding unit 31, a support unit 32, a liquid receiving cup 33, a recovery cup 34, and a drain port 35. The substrate holding unit 31 holds the wafer W horizontally. For example, the substrate holding unit 31 holds the outer edge portion of the wafer W from the lateral side.

The support unit 32 is a vertically extending member, and the lower base end portion of the support unit 32 is rotatably supported by a driving unit (not illustrated). In addition, although not illustrated in FIG. 3, the support unit 32 is able to support the substrate holding unit 31 horizontally at the upper tip end portion thereof.

The substrate processing unit 30 rotates the support unit 32 by using the driving unit, so that the substrate holding unit 31 supported by the support unit 32 is rotated. As a result, the substrate processing unit 30 rotates the wafer W held by the substrate holding unit 31. In addition, the support unit 32 is configured to be vertically movable, and is able to move toward the carried-in wafer W above the substrate processing unit 30 so as to receive the wafer W.

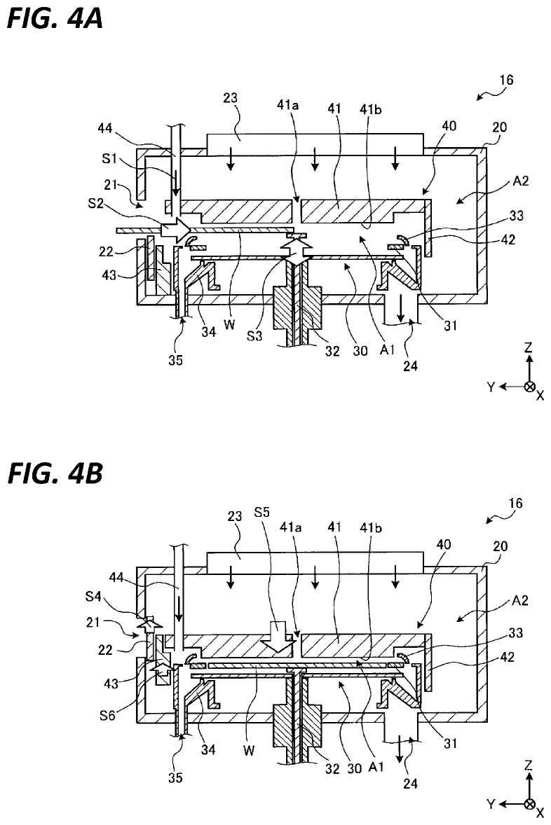

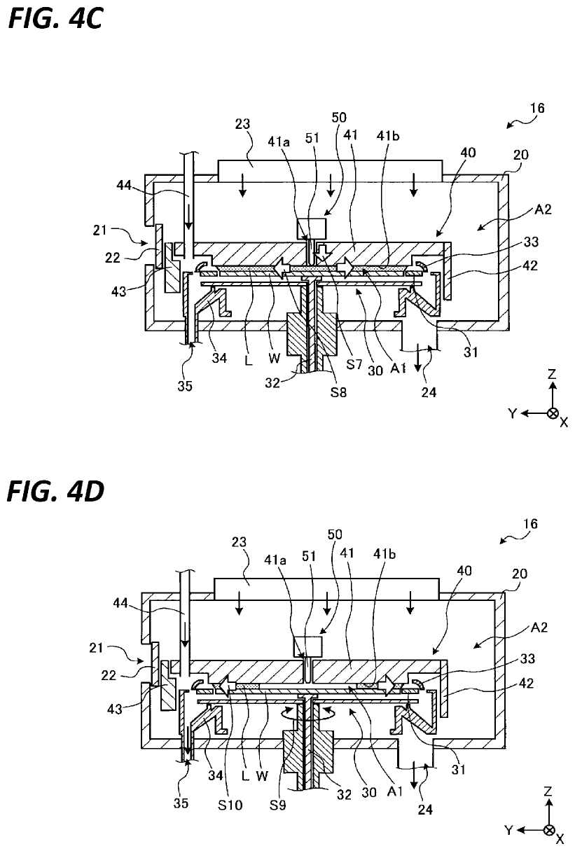

The liquid receiving cup 33 is of a substantially ring shape and has a curved shape which is recessed downward. The liquid receiving cup 33 is disposed to surround the outer edge portion of the substrate holding unit 31, and collects the processing liquid L (see FIG. 4C) scattered from the wafer W by the rotation of the substrate holding unit 31. For example, the liquid receiving cup 33 is disposed to surround the outer edge portion of the substrate holding unit 31 at a side at least higher than the plane of the substrate holding unit 31 which is the same as the plane of the wafer W held by the substrate holding unit 31.

The recovery cup 34 is disposed to surround the substrate holding unit 31, and collects the processing liquid L scattered from the wafer W by the rotation of the substrate holding unit 31. In addition, although not illustrated in FIG. 3, the recovery cup 34 may be a multi-cup that is able to collect each of a plurality of processing liquids L.

A drain port 35 is formed on the bottom portion of the recovery cup 34. The processing liquid L collected by the liquid receiving cup 33 or the recovery cup 34 is drained from the drain port 35 to the outside of the processing unit 16.

The partition wall 40 serves as a partition wall between a first space A1 from the carry-in/out port 21 to the substrate processing unit 30 as described above and a second space A2 other than the first space A1, inside the housing 20. In addition, the partition wall 40 is configured to be able to adjust the atmosphere inside the first space A1 to a predetermined condition.

As illustrated in FIG. 3, the partition wall 40 includes a top plate portion 41, a side wall portion 42, a gap filling portion 43, and a gas supply unit 44. The top plate portion 41 has a substantially disc shape, and is provided to face the wafer W held by the substrate holding unit 31 substantially in parallel thereto, so as to cover the upper side of the wafer W.

In addition, the top plate portion 41 is configured to be vertically movable inside the housing 20, and moves to an upper side that does not interfere with the transfer path of the wafer W when the wafer W is carried in/out from the carry-in/out port 21. Meanwhile, when the wafer W is processed in the substrate processing unit 30, the top plate portion 41 moves to a lower side that approaches the wafer W. In addition, the disposition of the top plate portion 41 is not limited to the position described above, and may be freely changed according to a condition for processing the wafer W or a condition for cleaning the top plate portion 41.

In the top plate portion 41, a through hole 41a is formed to communicate vertically. For example, as illustrated in FIG. 2, the through hole 41a has a slit shape, and is formed to at least face the central portion of the wafer W held by the substrate holding unit 31. In addition, the through hole 41a is formed such that a processing liquid nozzle 51 to be described later can be inserted through the through hole 41a.

In addition, as illustrated in FIG. 3, the top plate portion 41 has a convex portion 41b that protrudes toward the wafer W. The convex portion 41b protrudes, for example, in a substantially column shape. The outer diameter of the convex portion 41b is larger than the outer diameter of the facing wafer W and smaller than the inner diameter of the adjacent liquid receiving cup 33.

The side wall portion 42 surrounds the lateral side of, for example, the substrate holding unit 31 that holds the wafer W, the liquid receiving cup 33, or the top plate portion 41. For example, as illustrated in FIG. 2, in the top view, the side wall portion 42 has a linear shape at the front side on which the carry-in/out port 21 is formed, and a semicircular shape that conforms to the shape of the wafer W at the back side on which the wafer W is subjected to the liquid processing.

In the exemplary embodiment, the side wall portion 42 is movable up and down integrally with the top plate portion 41. Meanwhile, the side wall portion 42 does not need to move up and down together with the top plate portion 41, and may be fixed inside the housing 20. In this case, the top plate portion 41 may be configured to be movable up and down along the fixed side wall portion 42.

The gap filling portion 43 fills a gap other than the substrate processing unit 30 in the first space A1 (e.g., the periphery of the carry-in/out port 21) when the wafer W is processed in the substrate processing unit 30. In addition, the gap filling portion 43 is configured to be movable inside the housing 20, and moves to a position that does not interfere with the transfer path of the wafer W when the wafer W is carried into/out of the carry-in/out port 21. For example, as illustrated in FIG. 2, in the top view, the gap filling portion 43 has a substantially U shape of which the inner side has an arc shape and the outer side has a rectangular shape.

The gas supply unit 44 is connected to the first space A1, and supplies the atmosphere adjustment gas into the first space A1. For example, an ejection nozzle of the atmosphere adjustment gas in the gas supply unit 44 is provided in the top plate portion 41 between the carry-in/out port 21 and the substrate processing unit 30. In addition, the atmosphere adjustment gas may be supplied from a second gas supply unit (not illustrated) provided in the transfer section 15, via the transfer section 15.

In the exemplary embodiment, the atmosphere adjustment gas is, for example, an inert gas of which an oxygen concentration is lower than that of the air atmosphere such as nitrogen gas or Ar gas, or a gas of which a humidity is lower than that of the air atmosphere such as a drying gas.

The liquid supply unit 50 illustrated in FIG. 2 supplies the processing liquid L to the wafer W held in the first space A1. The liquid supply unit 50 includes a processing liquid nozzle 51, a nozzle bus 52, an arm 53, and an LM guide 54, and is disposed in the second space A2.

The processing liquid nozzle 51 is connected to a processing liquid supply source via a valve and a flow rate regulator (not illustrated), and ejects the processing liquid L to the wafer W by using the through hole 41a formed in the top plate portion 41.

The processing liquid L ejected from the processing liquid nozzle 51 includes various liquids used for various liquid processings of the wafer W, such as, for example, an acid processing liquid, an alkaline processing liquid, an organic processing liquid, and a rinsing liquid. The acid processing liquid is, for example, diluted hydrofluoric acid (DHF). The alkaline processing liquid is, for example, SC1 (a mixed solution of ammonia, hydrogen peroxide, and water). The organic processing liquid is, for example, isoprophyl alcohol (IPA). The rinsing liquid is, for example, deionized water (DIW).

The nozzle bus 52 is a container for causing the processing liquid nozzle 51 to stand by at a standby position and performing a dummy-dispense of the processing liquid L from the processing liquid nozzle 51. The arm 53 supports the processing liquid nozzle 51.

The LM guide 54 guides the arm 53 in the X axis direction. When a driving force is transferred from a driving unit (not illustrated) included in the LM guide 54, the arm 53 guided by the LM guide 54 slides along the LM guide 54 together with the processing liquid nozzle 51. As a result, the processing liquid nozzle 51 may be caused to slide to a predetermined position inside the housing 20.

In addition, the arm 53 is provided with a lifting mechanism (not illustrated). The liquid supply unit 50 may move the processing liquid nozzle 51 up and down by operating the lifting mechanism.

In this way, the liquid supply unit 50 may operate the LM guide 54 and the lifting mechanism so as to move the processing liquid nozzle 51 to the position of the through hole 41a and insert the processing liquid nozzle 51 through the through hole 41a.

In addition, in the exemplary embodiment, since the through hole 41a has the slit shape and the extension direction of the LM guide 54 and the extension direction of the through hole 41a are substantially parallel with each other, the processing liquid nozzle 51 may be caused to move while scanning in the through hole 41a.

In addition, while the example illustrated in FIG. 2 represents a case where two sets each including the processing liquid nozzle 51, the nozzle bus 52, and the arm 53 are provided, the number of sets each including the processing liquid nozzle 51, the nozzle bus 52, and the arm 53 to be provided in the processing unit 16 is not limited to two and may be a predetermined number.

In addition, while the example illustrated in FIG. 2 represents a case where the processing liquid nozzle 51 is fixed to the arm 53, the present disclosure is not limited to the case where the processing liquid nozzle 51 is fixed to the arm 53. The processing liquid nozzle 51 may be, for example, a pickup nozzle. In addition, the mechanism that causes the arm 53 to slide is not limited to the LM guide 54, and various known mechanisms may be used.

<Details of Liquid Processing>

Subsequently, details of the liquid processing according to the exemplary embodiment will be described with reference to FIGS. 4A to 4D. FIGS. 4A to 4D are schematic views (1) to (4) each illustrating a process of the liquid processing according to the exemplary embodiment.

As illustrated in FIG. 4A, in the processing unit 16, the transfer path of the wafer W in the first space A1 is secured before the wafer W is carried into the substrate processing unit 30. Specifically, the processing unit 16 causes the top plate portion 41 to retreat upward from the transfer path of the wafer W, and causes the gap filling portion 43 to retreat downward.

Further, the processing unit 16 supplies a predetermined atmosphere adjustment gas into the first space A1 by using the gas supply unit 44 from a predetermined timing before the wafer W is carried into the substrate processing unit 30 (step S1). As a result, the processing unit 16 may replace the atmosphere inside the first space A1 with the atmosphere adjustment gas in advance.

In the meantime, the second space A2 of the processing unit 16 is in the air atmosphere cleaned by using the FFU 23. Then, the atmosphere adjustment gas supplied into the first space A1 and the air atmosphere supplied into the second space A2 are exhausted in common through the exhaust port 24.

Subsequently, the processing unit 16 moves the shutter 22 to open the carry-in/out port 21. Then, the substrate transfer device 17 carries the wafer W into the processing unit 16 (step S2). Then, the processing unit 16 causes the wafer W carried up to the upper side of the substrate holding unit 31 to be taken by the upwardly moved support unit 32, and then, moves the support unit 32 downward such that the wafer W is held by the substrate holding unit 31 (step S3).

Subsequently, as illustrated in FIG. 4B, the processing unit 16 moves the shutter 22 to close the carry-in/out port 21 (step S4). Further, the processing unit 16 moves the top plate portion 41 downward to approach the wafer W (step S5). For example, in step S5, the top plate portion 41 approaches a position where the gap between the top plate portion 41 and the wafer W becomes about 1 mm to 4 mm.

Further, the processing unit 16 moves the gap filling portion 43 upward to fill the gap other than the substrate processing unit 30 in the first space A1 (step S6). The sequence of steps S4 to S6 illustrated in FIG. 4B is arbitrary, and for example, all of steps S4 to S6 may be performed simultaneously.

In the exemplary embodiment, during steps S4 to S6, the processing unit 16 operates the gas supply unit 44 to continuously supply the predetermined atmosphere adjustment gas into the first space A1. As a result, the atmosphere of the first space A1 in which the wafer W is disposed may be continuously adjusted to a predetermined condition.

Subsequently, as illustrated in FIG. 4C, the processing unit 16 operates the liquid supply unit 50 to move the processing liquid nozzle 51 to a predetermined position above the wafer W and insert the processing liquid nozzle 51 through the through hole 41a (step S7). Then, the processing unit 16 operates the processing liquid nozzle 51 to supply the predetermined processing liquid L to the wafer W (step S8).

In step S8, the processing unit 16 may rotate or stop the wafer W. In step S8, the liquid supply unit 50 may cause the processing liquid nozzle 51 to scan across the wafer W by a predetermined operation.

Subsequently, as illustrated in FIG. 4D, the processing unit 16 operates the substrate processing unit 30 to rotate the wafer W (step S9). As a result, the processing liquid L moves to the outer peripheral side of the wafer W so that the wafer W is processed with the liquid (step S10). The specific example of the liquid processing will be described later.

In the exemplary embodiment, during steps S7 to S10, the processing unit 16 operates the gas supply unit 44 to continuously supply the predetermined atmosphere adjustment gas into the first space A1. As a result, the atmosphere around the wafer W which is being subjected to the liquid processing may be continuously adjusted to a predetermined condition.

Here, in the exemplary embodiment, the air atmosphere is supplied into the second space A2 inside the housing 20, and the atmosphere adjustment gas is supplied only into the first space A1 defined by the partition wall 40. Thus, according to the exemplary embodiment, the use amount of the atmosphere adjustment gas during the liquid processing on the wafer W may be reduced.

In addition, in the exemplary embodiment, the top plate portion 41 approaches the wafer W, and the gap filling portion 43 fills the gap of the first space A1, so that the first space A1 may be made narrow. Thus, according to the exemplary embodiment, the use amount of the atmosphere adjustment gas may be further reduced.

In addition, in the exemplary embodiment, the inner diameter of the liquid receiving cup 33 may be larger than the outer diameter of the convex portion 41b of the top plate portion 41. As a result, as illustrated in, for example, FIG. 4B, the top plate portion 41 may approach the wafer W without interfering with the liquid receiving cup 33. Thus, according to the exemplary embodiment, the use amount of the atmosphere adjustment gas may be further reduced.

In addition, in the exemplary embodiment, as illustrated in FIGS. 4C and 4D, the space between the top plate portion 41 and the wafer W may be filled with the processing liquid L when the wafer W is subjected to the liquid processing. As a result, the film thickness of the processing liquid L on the wafer W at the time of the liquid processing may be made uniform. Thus, according to the exemplary embodiment, the liquid processing on the wafer W may be performed satisfactorily.

In addition, in the exemplary embodiment, the space between the top plate portion 41 and the wafer W is filled with the processing liquid L, so that the processing liquid L evaporated during a high temperature processing is suppressed from adhering to the top plate portion 41. In addition, in the exemplary embodiment, the space between the top plate portion 41 and the wafer W is filled with the processing liquid L, so that the processing liquid L may be easily heated by a heating unit (e.g., a heater) separately added to the top plate portion 41.

In addition, in the exemplary embodiment, even when the space between the top plate portion 41 and the wafer W is filled with the processing liquid L, the processing liquid L on the surface of the top plate portion 41 may be moved to the outer peripheral side of the top plate portion 41 together with the processing liquid L on the surface of the wafer W, by starting the rotation of the wafer W at a relatively low speed, and gradually increasing the rotation speed. As a result, in the exemplary embodiment, the processing liquid L may be suppressed from remaining on the surface of the top plate portion 41 after the liquid processing.

In addition, in the exemplary embodiment, as illustrated in, for example, FIG. 4D, the outer diameter of the convex portion 41b of the top plate portion 41 may be larger than the outer diameter of the wafer W. As a result, even when the processing liquid L remains on the outer edge portion of the convex portion 41b after the liquid processing, the remaining processing liquid L may be suppressed from adhering to the wafer W.

In addition, when the processing liquid L remains on the outer edge portion of the convex portion 41b after the liquid processing, the processing liquid L remaining on the outer edge portion may be purged with, for example, the atmosphere adjustment gas.

In addition, in the exemplary embodiment, the through hole 41a may be formed to face at least the central portion of the wafer W held by the substrate holding unit 31. As a result, the processing liquid nozzle 51 may be disposed above the central portion of the wafer W, and the processing liquid L may be ejected to the central portion of the wafer W. Thus, according to the exemplary embodiment, the processing liquid L may be uniformly supplied to the entire surface of the wafer W.

The description of the processing in the processing unit 16 will be continued. After the liquid processing is completed, the processing unit 16 causes the top plate portion 41 to retreat upward from the transfer path of the wafer W, and causes the gap filling portion 43 to retreat downward, so as to secure the transfer path of the wafer W in the first space A1.

Then, the shutter 22 is moved to open the carry-in/out port 21, and the wafer W is carried out from the processing unit 16 by using the substrate transfer device 17. Finally, the processing unit 16 closes the shutter 22, and stops the supply of the atmosphere adjustment gas by the gas supply unit 44.

In this way, by stopping the supply of the atmosphere adjustment gas into the first space A1 from which the wafer W has been carried out, the use amount of the atmosphere adjustment gas may be further reduced.

In addition, in the exemplary embodiment, as described above, the supply of the atmosphere adjustment gas by the gas supply unit 44 may be started before the wafer W is carried into, so as to replace the first space A1 with the atmosphere adjustment gas in advance. As a result, the wafer W may be carried into the first space A1 in which the atmosphere has been adjusted.

In addition, in the exemplary embodiment, the substrate holding unit 31 may be rotated in the first space A1 when the first space A1 is replaced in advance with the atmosphere adjustment gas. As a result, an atmosphere other than the atmosphere adjustment gas may be suppressed from staying in the first space A1, and the first space A1 may be efficiently replaced with the atmosphere adjustment gas.

In addition, in the exemplary embodiment, since the first space A1 and the second space A2 communicate with each other through the through hole 41a, the air atmosphere of the second space A2 may flow into the first space A1 through the through hole 41a.

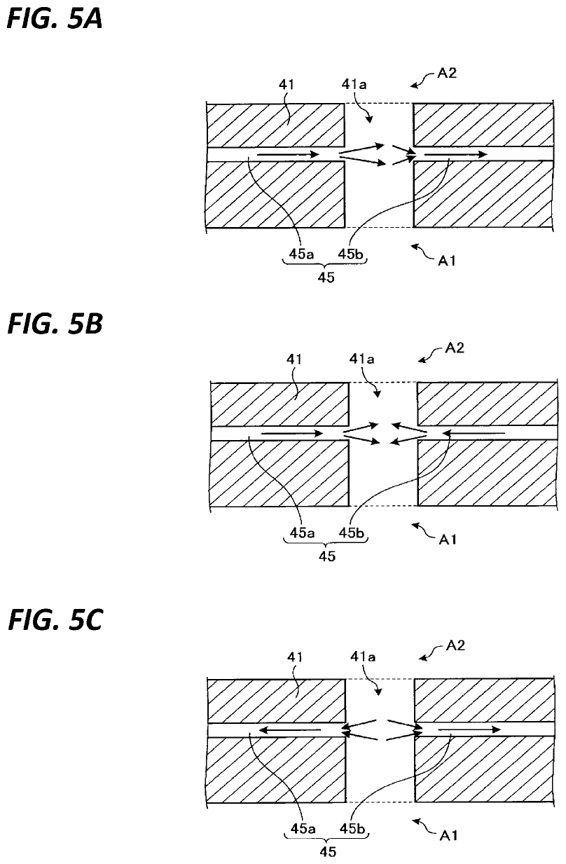

Accordingly, in the exemplary embodiment, an inflow suppression unit 45 (see FIG. 5A) is provided to suppress the inflow of the air atmosphere into the first space A1. Subsequently, the details of the inflow suppression unit 45 will be described with reference to FIGS. 5A to 5C.

FIG. 5A is a schematic view for explaining an example of the inflow suppression unit 45 according to the exemplary embodiment, and schematically represents the cross-section of the portion of the top plate portion 41 including the through hole 41a. As illustrated in FIG. 5A, the inflow suppression unit 45 includes a first pipe portion 45a and a second pipe portion 45b.

The first pipe portion 45a and the second pipe portion 45b are connected to the opposing positions on the inner wall of the through hole 41a. The first pipe portion 45a is connected to a gas supply mechanism (not illustrated) that supplies, for example, the atmosphere adjustment gas, and ejects the gas supplied from the gas supply mechanism into the through hole 41a.

The second pipe portion 45b is connected to an exhaust mechanism (not illustrated), and exhausts the atmosphere inside the through hole 41a by the exhaust mechanism. In this way, the inflow suppression unit 45 may form a so-called gas curtain in the through hole 41a, by exhausting the gas ejected from the first pipe portion 45a, through the opposing second pipe portion 45b.

As a result, the air atmosphere of the second space A2 may be suppressed from flowing into the first space A1. Thus, according to the exemplary embodiment, the first space A1 may be satisfactorily maintained in the atmosphere adjusted to the predetermined condition. In addition, in the example illustrated in FIG. 5A, the gas ejected from the second pipe portion 45b may be exhausted through the opposing first pipe portion 45a.

FIG. 5B is a schematic view for explaining another example of the inflow suppression unit 45 according to the exemplary embodiment. In the example of FIG. 5B, for example, the atmosphere adjustment gas is ejected from both the first pipe portion 45a and the second pipe portion 45b. In this case as well, the gas curtain may be formed in the through hole 41a.

Thus, in the example of FIG. 5B as well, the air atmosphere of the second space A2 may be suppressed from flowing into the first space A1, so that the first space A1 may be satisfactorily maintained in the atmosphere adjusted to the predetermined condition.

FIG. 5C is a schematic view for explaining another example of the inflow suppression unit 45 according to the exemplary embodiment. In the example of FIG. 5C, for example, the atmosphere adjustment gas is ejected from both the first pipe portion 45a and the second pipe portion 45b. As a result, the air atmosphere that flows into the through hole 41a from the second space A2 may be exhausted to the outside by using the first pipe portion 45a and the second pipe portion 45b.

Thus, in the example of FIG. 5C as well, the air atmosphere of the second space A2 may be suppressed from flowing into the first space A1, so that the first space A1 may be satisfactorily maintained in the atmosphere adjusted to the predetermined condition.

In addition, in the exemplary embodiment, an example has been described in which the processing liquid L is supplied to the wafer W in a state where the processing liquid nozzle 51 is inserted through the through hole 41a. Meanwhile, the processing liquid L may be supplied to the wafer W by flowing through the through hole 41a from the processing liquid nozzle 51 disposed above the through hole 41a, without inserting the processing liquid nozzle 51 through the through hole 41a.

Meanwhile, the processing liquid L is supplied to the wafer W in the state where the processing liquid nozzle 51 is inserted through the through hole 41a, so that the processing liquid L may be ejected from the side of the processing liquid nozzle 51 which is closer to the first space A1 than the inflow suppression unit 45 described above. That is, the inflow suppression unit 45 may function sufficiently, as compared with the case where the processing liquid L flows through the through hole 41a.

Thus, according to the exemplary embodiment, the processing liquid L is supplied to the wafer W in the state where the processing liquid nozzle 51 is inserted through the through hole 41a, so that the first space A1 may be satisfactorily maintained in the atmosphere adjusted to the predetermined condition.

<Modifications>

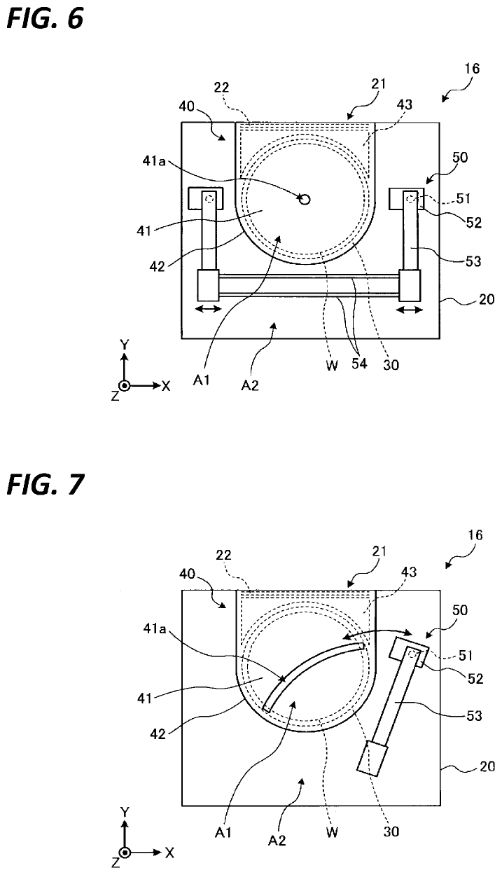

Subsequently, various modifications of the processing unit 16 according to the exemplary embodiment will be described with reference to FIGS. 6 to 9C. FIG. 6 is a top view illustrating a configuration of a processing unit 16 according to Modification 1 of the exemplary embodiment.

In Modification 1 illustrated in FIG. 6, the through hole 41a has the same shape as that of the processing liquid nozzle 51 to be inserted through the through hole 41a (e.g., a substantially circular shape), instead of the slip shape. In Modification 1 as well, the through hole 41a may be disposed to face the central portion of the wafer W held by the substrate holding unit 31, so that the processing liquid L may be uniformly supplied to the entire surface of the wafer W.

FIG. 7 is a top view illustrating a configuration of a processing unit 16 according to Modification 2 of the exemplary embodiment. In Modification 2 illustrated in FIG. 7, the through hole 41a is an arc-shaped slit, instead of the linear slit.

In Modification 2, the liquid supply unit 50 is configured to enable the processing liquid nozzle 51 to pivot along the through hole 41a, so that the processing liquid nozzle 51 may move while scanning in the through hole 41a, as in the exemplary embodiment.

In Modification 2 as well, the through hole 41a is disposed to face at least the central portion of the wafer W, so that the processing liquid L may be uniformly supplied to the entire surface of the wafer W.

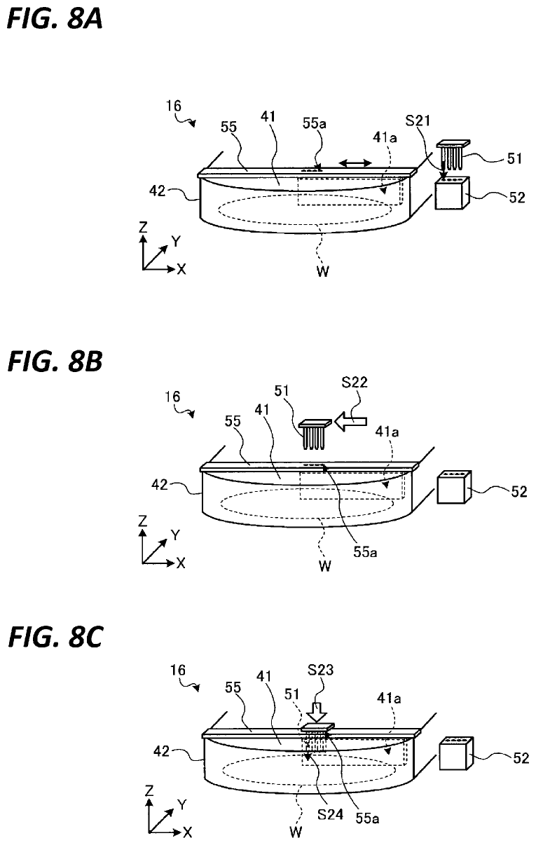

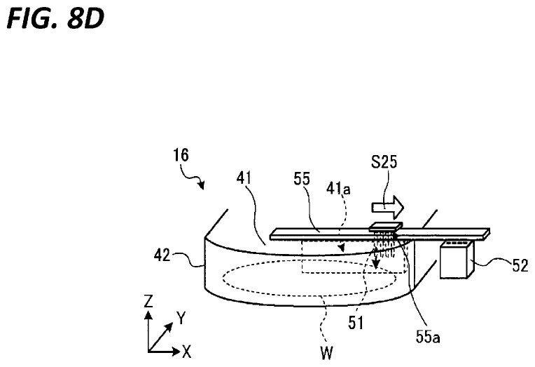

Next, Modification 3 of the processing unit 16 will be described with reference to FIGS. 8A to 8D. FIGS. 8A to 8D are schematic views (1) to (4) each illustrating a process of a liquid processing by a processing unit 16 according to Modification 3 of the exemplary embodiment. Further, each of FIGS. 8A to 8D represents a schematic perspective view of the processing unit 16.

As illustrated in FIG. 8A, in the processing unit 16 of Modification 3, the slit-shaped through hole 41a is formed in the top plate portion 41 in a straight line form extending from the central portion to the outer edge portion of the wafer W. Further, a scanning top plate 55 is disposed to cover the through holes 41a and extend from one outer edge portion to the other outer edge portion of the wafer W. The scanning top plate 55 is configured to be movable along the through holes 41a.

Further, in the processing unit 16 of Modification 3, a plurality of processing liquid nozzles 51 are provided as a pickup nozzle. Further, a plurality of through holes 55a are formed in the scanning top plate 55 to allow the plurality of processing liquid nozzles 51 to be inserted through the through holes 55a.

In the processing unit 16 of Modification 3, first, a dummy dispense of the processing liquid L is performed from the processing liquid nozzles 51 (step S21).

Subsequently, as illustrated in FIG. 8B, the processing unit 16 picks up the processing liquid nozzles 51 by a transfer unit (not illustrated), and transfers the processing liquid nozzles 51 to the upper side of the central portion of the wafer W (step S22). At the time of step S22, the through holes 55a of the scanning top plate 55 are arranged above the central portion of the wafer W.

Subsequently, as illustrated in FIG. 8C, the processing unit 16 inserts the processing liquid nozzles 51 through the through hole 41a of the top plate portion 41 via the through holes 55a of the scanning top plate 55 (step S23). Then, the processing unit 16 supplies the processing liquid L to the wafer W from the processing liquid nozzles 51 inserted through the through hole 41a (step S24).

Subsequently, as illustrated in FIG. 8D, the processing unit 16 causes the processing liquid nozzles 51 from which the processing liquid L is being ejected, to scan across the wafer W while moving the processing liquid nozzles 51 in synchronization with the scanning top plate 55 (step S25). In addition, in step S25, the transfer unit that has picked up the processing liquid nozzles 51 may move the processing liquid nozzles 51, or the scanning top plate 55 may move the processing liquid nozzles 51.

As described above, in Modification 3, the through hole 41a is covered by the scanning top plate 55 that is moved in synchronization with the processing liquid nozzles 51, so that the air atmosphere of the second space A2 may be suppressed from flowing into the first space A1 via the through hole 41a. Thus, according to Modification 3, the first space A1 may be satisfactorily maintained in the atmosphere adjusted to the predetermined condition.

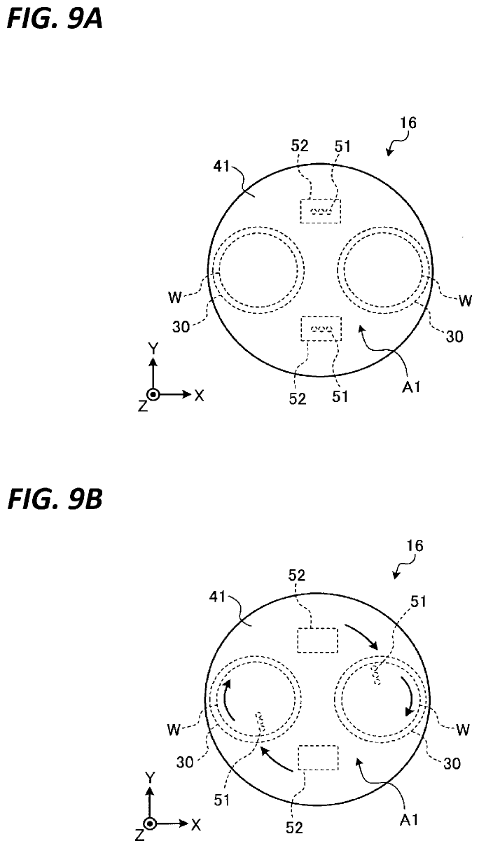

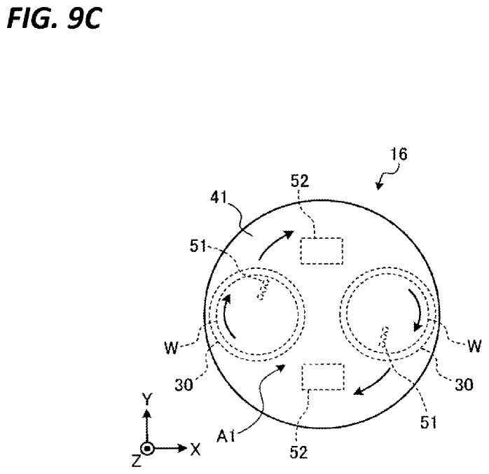

Subsequently, Modification 4 of the processing unit 16 will be described with reference to FIGS. 9A to 9C. FIGS. 9A to 9C are schematic views (1) to (3) each illustrating a process of a liquid processing by a processing unit 16 according to Modification 4 of the exemplary embodiment. Further, each of FIGS. 9A to 9C represents a schematic top view of the processing unit 16.

In Modification 4, a plurality of (e.g., two) substrate processing units 30 are provided in a single processing unit 16, and a plurality of wafers W may be collectively processed in the single processing unit 16. In Modification 4, the top plate portion 41 is disposed to cover all of the plurality of substrate processing units 30 and is configured to be rotatable above the substrate processing units 30.

Further, in Modification 4, the processing liquid nozzle 51 is provided in the top plate portion 41, and the nozzle bus 52 is provided inside the first space A1 defined by, for example, the top plate portion 41. In addition, FIG. 9A represents an example where two sets each including three processing liquid nozzles 51 and one nozzle bus 52 are provided.

As illustrated in FIG. 9A, in the processing unit 16 of Modification 4, first, a dummy dispense of the processing liquid L is performed from the processing liquid nozzles 51 disposed above the nozzle bus 52. Subsequently, as illustrated in FIG. 9B, the processing unit 16 rotates the top plate portion 41 to move the processing liquid nozzles 51 to the upper side of the wafer W.

Then, the processing unit 16 supplies the processing liquid L from the processing liquid nozzles 51 to the wafer W while rotating the wafer W in the substrate processing unit 30.

As illustrated in FIG. 9C, the processing unit 16 further rotates the top plate portion 41 while supplying the processing liquid L from the processing liquid nozzles 51, so as to cause the processing liquid nozzles 51 to scan across the wafer W.

As described above, in Modification 4, the processing liquid L may be supplied to the plurality of wafers W in the first space A1 which is defined by, for example, the top plate portion 41 and of which the atmosphere has been adjusted by the atmosphere adjustment gas.

In addition, in Modification 4, as illustrated in, for example, FIG. 9A, the processing liquid nozzles 51 may be provided as many as the number of the substrate process units 30. As a result, in Modification 4, the plurality of wafers W accommodated in the processing unit 16 may be subjected to the liquid processing at the same time.

In addition, in Modification 4, the processing liquid nozzles 51 may be disposed to pass at least the central portion of the wafer W when the top plate portion 41 is rotated. As a result, the processing liquid L may be uniformly supplied to the entire surface of the wafer W.

The substrate processing apparatus (processing unit 16) according to the exemplary embodiment includes the substrate processing unit 30, the partition wall 40, and the liquid supply unit 50. The substrate processing unit 30 performs the liquid processing on the substrate (wafer W). The partition wall 40 serves as a partition wall between the first space A1 from the carry-in/out port 21 through which the substrate (wafer W) is carried in/out, to the substrate processing unit 30 and the second space A2 other than the first space A1. The liquid supply unit 50 is provided in the second space A2, and supplies the processing liquid L to the substrate (wafer W). As a result, the use amount of the atmosphere adjustment gas during the liquid processing on the wafer W may be reduced.

In addition, the substrate processing apparatus (processing unit 16) according to the exemplary embodiment further includes the gas supply unit 44 that supplies the atmosphere adjustment gas for adjusting the atmosphere into the first space A1. As a result, the atmosphere adjustment gas may be supplied only into the first space A1 defined by the partition wall 40.

In addition, in the substrate processing apparatus (processing unit 16) according to the exemplary embodiment, the partition wall 40 includes the top plate portion 41 that covers the upper side of the substrate (wafer W), and the side wall portion 42 that surrounds the lateral side of the substrate (wafer W). As a result, the upper side and the lateral side of the wafer W held by the substrate processing unit 30 may be defined by the partition wall 40.

In addition, the substrate processing apparatus (processing unit 16) according to the exemplary embodiment further includes the housing 20 that accommodates the substrate processing unit 30, the partition wall 40, and the liquid supply unit 50. The second space A2 in the housing 20 is in the air atmosphere. As a result, the use amount of the atmosphere adjustment gas during the liquid processing on the wafer W may be reduced.

In the substrate processing system 1 according to the exemplary embodiment, the plurality of substrate processing apparatuses (processing units 16) described above are arranged. Further, the substrate processing system 1 includes the common transfer path (transfer section 15) where the transfer mechanism (substrate transfer device 17) is provided to transfer the substrate (wafer W) to each of the substrate processing apparatuses, adjacent to the plurality of substrate processing apparatuses. As a result, it is possible to implement the substrate processing system 1 capable of reducing the use amount of the atmosphere adjustment gas during the liquid processing on the wafer W.

In addition, the substrate processing system 1 according to the exemplary embodiment further includes the second gas supply unit that supplies the atmosphere adjustment gas for adjusting the atmosphere to the common transfer path (transfer section 15). As a result, the wafer W may be transferred in the atmosphere adjusted by the atmosphere adjustment gas even before the wafer W is transferred to the processing units 16.

<Details of Liquid Processing>

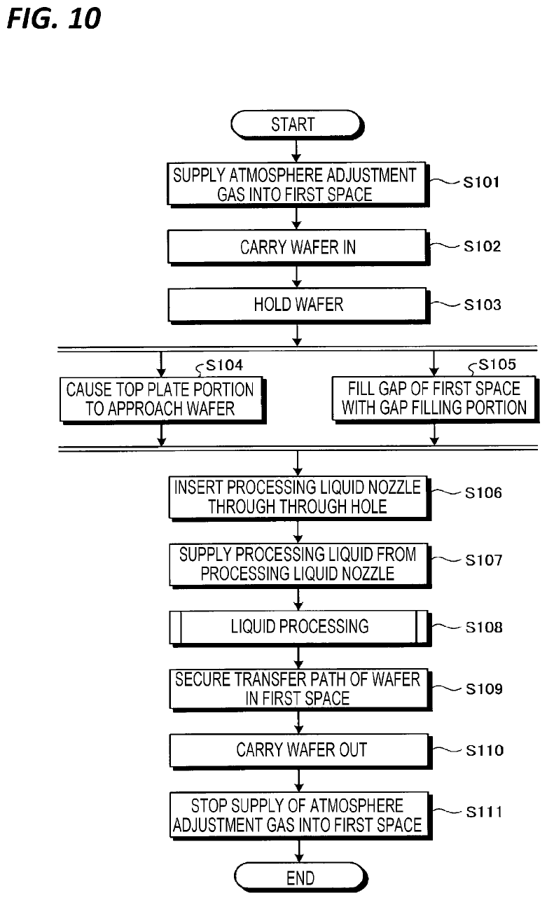

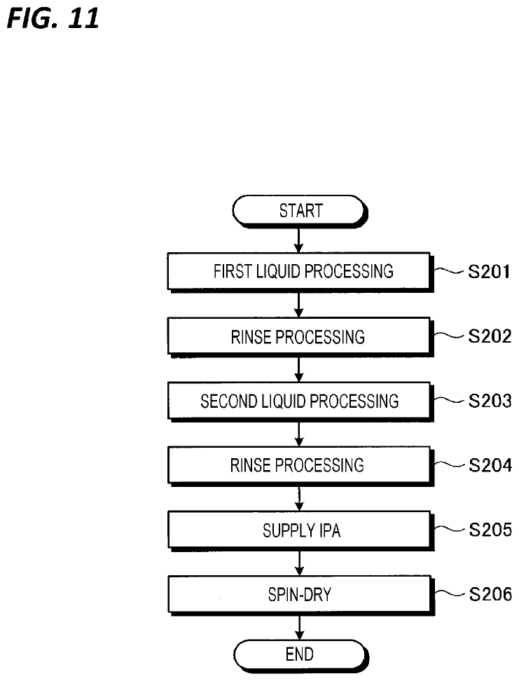

Subsequently, details of the liquid processing according to the exemplary embodiment will be described with reference to FIGS. 10 and 11. FIG. 10 is a flowchart illustrating a procedure of the entire liquid processing according to the exemplary embodiment.

The liquid processing illustrated in FIGS. 10 and 11 is performed in the manner that the controller 18 reads out programs installed in the storage unit 19 from a storage medium according to the exemplary embodiment, and controls, for example, the transfer section 12 or the transfer section 15, and the processing unit 16 based on read-out commands.

First, the controller 18 controls the gas supply unit 44 of the processing unit 16 to supply the atmosphere adjustment gas into the first space A1 defined by the partition wall 40 (step S101). Subsequently, the controller 18 controls the substrate transfer device 13 and the substrate transfer device 17 to transfer the wafer W from the carrier C into the processing unit 16 via the substrate transfer device 13, the delivery unit 14, and the substrate transfer device 17 (step S102).

Subsequently, the controller 18 controls the substrate processing unit 30 of the processing unit 16 to hold the wafer W in the substrate holding unit 31 (step S103). For example, step S103 is performed by causing the wafer W carried in up to the upper side of the substrate holding unit 31 to be taken by the upwardly moved supply unit 32, and then, moving the support unit 32 downward such that the wafer W is held by the substrate holding unit 31.

Subsequently, the controller 18 controls the partition wall 40 of the processing unit 16 to cause the top plate portion 41 to approach the wafer W (step S104). Further, in parallel with the process of step S104, the controller 18 controls the partition wall 40 to fill the gap of the first space A1 with the gap filling portion 43 (step S105).

Subsequently, the controller 18 controls the liquid supply unit 50 of the processing unit 16 to insert the processing liquid nozzle 51 through the through hole 41a of the top plate portion 41 (step S106). Then, the controller 18 controls the liquid supply unit 50 to supply the processing liquid L to the wafer W from the processing liquid nozzle 51 (step S107).

Subsequently, the controller 18 controls the substrate processing unit 30 to perform the liquid processing on the wafer W (step S108). For example, step S108 is performed by rotating the substrate holding unit 31 so as to rotate the wafer W, and moving the processing liquid L supplied to the wafer W to the outer peripheral side of the wafer W. In addition, steps S107 and S108 may be performed by suppressing the processing liquid L from contacting the top plate portion 41, or by filling the space between the top plate portion 41 and the wafer W with the processing liquid L.

Subsequently, the controller 18 controls the partition wall 40 to secure the transfer path of the wafer W in the first space A1 (step S109). For example, step S109 is performed by causing the top plate portion 41 to retreat upward from the transfer path of the wafer W and causing the gap filling portion 43 to retreat downward.

Subsequently, the controller 18 controls the substrate processing unit 30, the substrate transfer device 17, and the substrate transfer device 13, to carry the wafer W out from the processing unit 16 into the carrier C via the substrate transfer device 17, the delivery unit 14, and the substrate transfer device 13.

Finally, the controller 18 controls the gas supply unit 44 to stop the supply of the atmosphere adjustment gas into the first space A1 defined by the partition wall 40 (step S111), and completes the process.

FIG. 11 is a flowchart illustrating a detailed procedure of the liquid processing (step S108 described above) according to the exemplary embodiment.

In the liquid processing of the exemplary embodiment, first, a first liquid processing is performed with a predetermined first processing liquid (step S201). For example, the first liquid processing is performed by supplying the first processing liquid which is an acid processing liquid such as DHF or an alkaline processing liquid such as SC1, to the wafer W from the processing liquid nozzle 51.

Subsequently, a rinse processing is performed with a predetermined rinsing liquid (step S202). For example, the rinse processing is performed by supplying a rinsing liquid such as, for example, DIW to the wafer W from the processing liquid nozzle 51. In addition, when the rinse processing is performed by filling the space between the top plate portion 41 and the wafer W with the rinsing liquid, the first processing liquid adhering to the top plate portion 41 may also be removed from the surface of the top plate portion 41.

In addition, when the rinse processing is performed by suppressing the rinsing liquid from contacting the top plate portion 41, the first processing liquid adhering to the top plate portion 41 may be removed from the surface of the top plate portion 41 by changing the height of the top plate portion 41 so as to bring the rinsing liquid into contact with the top plate portion 41.

Subsequently, a second liquid processing is performed with a predetermined second processing liquid (step S203). For example, the second liquid processing is performed by supplying a second processing liquid which is an acid processing liquid such as DHF or an alkaline processing liquid such as SC1, to the wafer W from the processing liquid nozzle 51.

Subsequently, a rinse processing is performed with a predetermined rinsing liquid (step S204). The rinse processing is the same as the processing in step S202. In addition, when the rinse processing is performed by filling the space between the top plate portion 41 and the wafer W with the rinsing liquid, the second processing liquid adhering to the top plate portion 41 may also be removed from the surface of the top plate portion 41.

In addition, when the rinse processing is performed by suppressing the rinsing liquid from contacting the top plate portion 41, the second processing liquid adhering the top plate portion 41 may be removed from the surface of the top plate portion 41 by changing the height of the top plate portion 41 so as to bring the rinsing liquid into contact with the top plate portion 41.

Subsequently, IPA is supplied to the wafer W by using the processing liquid nozzle 51 (step S205). Finally, the wafer W to which the IPA has been supplied is rotated and spin-dried (step S206), and the processing is completed.

The substrate processing method according to the exemplary embodiment includes: supplying an atmosphere adjustment gas; carrying a substrate (wafer W) into the first space A1; placing the substrate (wafer W) on the substrate processing unit 30; and performing a liquid processing. The supplying an atmosphere adjustment gas supplies an atmosphere adjustment gas for adjusting an atmosphere into the first space A1 from the carry-in/out port 21 through which the substrate (wafer W) is carried in/out to the substrate processing unit 30 that performs the liquid processing on the substrate (wafer W). The performing a liquid processing performs a liquid processing on the substrate (wafer W) by using the liquid supply unit 50 disposed in the second space A2 defined by the partition wall 40 from the first space A1. As a result, the use amount of the atmosphere adjustment gas during the liquid processing on the wafer W may be reduced.

The substrate processing method according to the exemplary embodiment further includes carrying the substrate (wafer W) out from the substrate processing unit 30, and stopping the supply of the atmosphere adjustment gas into the first space A1 after the carry-out of the substrate (wafer W). As a result, the use amount of the atmosphere adjustment gas may be further reduced.

The substrate processing method according to the exemplary embodiment further includes causing the top plate portion 41 of the partition wall 40 that covers the upper side of the substrate (wafer W) to approach the substrate (wafer W) placed on the substrate processing unit 30. As a result, the first space A1 may be narrowed, and the use amount of the atmosphere adjustment gas may be further reduced.

In the substrate processing method according to the exemplary embodiment, the performing a liquid processing includes filling the space between the top plate portion 41 and the substrate (wafer W) with the processing liquid L. As a result, the liquid processing of the wafer W may be performed satisfactorily.

According to the present disclosure, the use amount of the atmosphere adjustment gas during the processing of the substrate may be reduced.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a substrate processing unit that includes a substrate holder and performs a liquid processing on a substrate;
a partition wall that partitions a first space from a carry-in/out port through which the substrate is carried in/out to the substrate processing unit, and a second space other than the first space; and
a liquid supply source that is provided in the second space and supplies a processing liquid to the substrate.

2. The substrate processing apparatus according to claim 1, further comprising:
a gas supply source that supplies an atmosphere adjustment gas into the first space.

3. The substrate processing apparatus according to claim 2, wherein the partition wall includes a top plate that covers an upper side of the substrate, and a side wall that surrounds a lateral side of the substrate.

4. The substrate processing apparatus according to claim 2, further comprising:
a housing that accommodates the substrate processing unit, the partition wall, and the liquid supply source,
wherein the second space in the housing is in an air atmosphere.

5. A substrate processing system comprising:
a plurality of substrate processing apparatuses according to claim 2, and
a common transfer path in which a transfer mechanism is provided adjacent to the plurality of substrate processing apparatuses to transfer a substrate to each of the plurality of substrate processing apparatuses.

6. The substrate processing apparatus according to claim 2, further comprising:
a second gas supply source that supplies an atmosphere adjustment gas to the common transfer path.

7. The substrate processing apparatus according to claim 1, wherein the partition wall includes a top plate that covers an upper side of the substrate, and a side wall that surrounds a lateral side of the substrate.

8. The substrate processing apparatus according to claim 7, further comprising:
a housing that accommodates the substrate processing unit, the partition wall, and the liquid supply source,
wherein the second space in the housing is in an air atmosphere.

9. A substrate processing system comprising:
a plurality of substrate processing apparatuses according to claim 7, and
a common transfer path in which a transfer mechanism is provided adjacent to the plurality of substrate processing apparatuses to transfer the substrate to each of the plurality of substrate processing apparatuses.

10. The substrate processing apparatus according to claim 7, further comprising:
a second gas supply source that supplies an atmosphere adjustment gas to the common transfer path.

11. The substrate processing apparatus according to claim 1, further comprising:
a housing that accommodates the substrate processing unit, the partition wall, and the liquid supply source,
wherein the second space in the housing is in an air atmosphere.

12. A substrate processing system comprising:
a plurality of substrate processing apparatuses according to claim 11, and
a common transfer path in which a transfer mechanism is provided adjacent to the plurality of substrate processing apparatuses to transfer the substrate to each of the plurality of substrate processing apparatuses.

13. A substrate processing method comprising:
providing a substrate processing apparatus including a substrate processing unit that performs a liquid processing on a substrate, a partition wall that partitions a first space from a carry-in/out port through which the substrate is carried in/out to the substrate processing unit and a second space other than the first space;
supplying an atmosphere adjustment gas into the first space;
carrying the substrate into the first space and placing the substrate on the substrate processing unit; and
performing the liquid processing on the substrate using a liquid supply source that is disposed in the second space.

14. The substrate processing method according to claim 13, further comprising:
carrying out the substrate that has been subjected to the liquid processing, from the substrate processing unit; and
stopping the supply of the atmosphere adjustment gas into the first space, after the substrate is carried out.

15. The substrate processing method according to claim 14, further comprising:
causing a top plate portion of the partition wall that covers an upper side of the substrate, to approach the substrate placed on the substrate processing unit.

16. The substrate processing method according to claim 13, further comprising:
causing a top plate portion of the partition wall that covers an upper side of the substrate, to approach the substrate placed on the substrate processing unit.

17. The substrate processing method according to claim 16, where the performing the liquid processing includes filling a space between the top plate portion and the substrate with a processing liquid.
